(19) United States
(12) Patent Application Publication
(10) Pub. No.: US 2017/0205480 A1
(43) Pub. Date: Jul. 20, 2017

(54) LOCAL COIL APPARATUS, MAGNETIC RESONANCE IMAGING (MRI) APPARATUS, AND CONTROL METHOD OF THE LOCAL COIL APPARATUS

(71) Applicant: SAMSUNG ELECTRONICS CO., LTD., Suwon-si (KR)

(72) Inventor: Verghese GEORGE, Suwon-si (KR)

(73) Assignee: SAMSUNG ELECTRONICS CO., LTD., Suwon-si (KR)

(21) Appl. No.: 15/343,488

(22) Filed: Nov. 4, 2016

(30) Foreign Application Priority Data
Jan. 18, 2016 (KR) 10-2016-0006035

(51) Int. Cl. G01R 33/34; G01R 33/385; G01R 33/3415; G01R 33/36

(52) U.S. Cl. CPC G01R 33/34015; G01R 33/3628; G01R 33/385; G01R 33/3415

(57) ABSTRACT

A local coil apparatus, a magnetic resonance imaging apparatus, and a control method of the local coil apparatus are provided. The local coil apparatus includes a radio frequency (RF) receiving coil configured to receive an RF signal from an object, a temperature sensor configured to sense a temperature of the local coil apparatus, and a reactance controller configured to control a reactance of the RF receiving coil in response to the temperature of the local coil apparatus being greater than or equal to a reference value.

### CROSS-REFERENCE TO RELATED APPLICATION

This application claims priority from Korean Patent Application No. 10-2016-0006035, filed on Jan. 18, 2016, in the Korean Intellectual Property Office, the disclosure of which is incorporated herein by reference in its entirety.

### BACKGROUND

1. Field

Apparatuses and methods consistent with exemplary embodiments relate to a local coil apparatus, a Magnetic Resonance Imaging (MRI) apparatus, and a control method of the local coil apparatus.

2. Description of the Related Art

In general, a medical imaging apparatus is used to acquire a patient's information to provide images. Examples of the medical imaging apparatus include an X-ray imaging apparatus, an ultrasonic diagnosis apparatus, a Computerized Tomography (CT) scanner, and a Magnetic Resonance Imaging (MRI) apparatus.

The MRI apparatus allows relatively free image-taking conditions and can provide excellent contrast and various diagnosis information images with respect to soft tissue.

MRI causes a Nuclear Magnetic Resonance (NMR) phenomenon in hydrogen nuclei in the body, using Radio Frequency (RF) being ionization radiation and a magnetic field that is harmless to the human body, to image the density and physical and chemical properties of atomic nuclei.

In detail, the MRI apparatus applies a constant magnetic field to the inside of a gantry, and then supplies a predetermined frequency and energy to convert energy emitted from atomic nuclei into a signal, thereby imaging the inside of an object.

The MRI apparatus includes an RF transmitting coil to transmit RF pulses, and an RF receiving coil to receive electromagnetic waves, that is, Magnetic Resonance (MR) signals emitted from excited atomic nuclei.

Also, the MRI apparatus includes a separate RF receiving coil so that it can receive data about an object from a local coil apparatus assisting the MRI apparatus.

The RF transmitting coil of the MRI apparatus applies RF pulses tuned to a frequency to an object, and the RF receiving coil of the local coil apparatus receives the RF pulses at the same frequency.

### SUMMARY

Exemplary embodiments may address at least the above problems and/or disadvantages and other disadvantages not described above. Also, the exemplary embodiments are not required to overcome the disadvantages described above, and may not overcome any of the problems described above.

Exemplary embodiments provide a local coil apparatus for controlling the reactance of a circuit when the temperature of the local coil apparatus rises to be greater than or equal to a predetermined level, to thereby reduce the temperature of the local coil apparatus, and a control method of the local coil apparatus.

Exemplary embodiments provide a Magnetic Resonance Imaging (MRI) apparatus for controlling the reactance of a circuit when the temperature of the MRI apparatus rises to be greater than or equal to a predetermined level, to thereby reduce the temperature of the MRI apparatus.

According to an aspect of an exemplary embodiment, there is provided a local coil apparatus including a radio frequency (RF) receiving coil configured to receive an RF signal from an object, a temperature sensor configured to sense a temperature of the local coil apparatus, and a reactance controller configured to control a reactance of the RF receiving coil in response to the temperature of the local coil apparatus being greater than or equal to a reference value.

The local coil apparatus may further include a decoupling circuit configured to increase an impedance of the RF receiving coil in an RF transmission mode in which the RF receiving coil ceases the reception of the RF signal from the object, and decrease the impedance of the RF receiving coil in an RF reception mode in which the RF receiving coil receives the RF signal from the object.

The temperature sensor may be further configured to sense a temperature of the decoupling circuit, and the reactance controller may be further configured to control a reactance of the decoupling circuit in response to the temperature of the decoupling circuit being greater than or equal to the reference value.

The decoupling circuit includes a diode, and the temperature sensor may be further configured to sense a temperature of the diode.

The diode may be a PIN diode.

The diode may be configured to receive a voltage in a forward direction in the RF transmission mode, and receive a voltage in a backward direction in the RF reception mode.

The decoupling circuit may include a capacitor, an inductor, and a diode, the inductor may be connected in series to the diode, and the inductor and the diode may be connected in parallel to the capacitor.

The reactance controller may be connected in parallel to the inductor.

The reactance controller may include a varactor diode.

The reactance controller may be further configured to reduce an RF reception frequency of the local coil apparatus in response to the temperature of the local coil apparatus being greater than or equal to the reference value.

According to an aspect of another exemplary embodiment, there is provided a local coil apparatus including a transceiver connected to a magnetic resonance imaging (MRI) apparatus and configured to transmit an RF signal to the MRI apparatus, a temperature sensor configured to sense a temperature of the transceiver, and a reactance controller configured to control a reactance of the transceiver in response to the temperature of the transceiver being greater than or equal to a reference value.

The local coil apparatus may further include an RF receiving coil connected to the transceiver and configured to receive the RF signal from an object.

The transceiver may include a cable.

The transceiver connected to the MRI apparatus may have a common mode trap.

The common mode trap may include an impedance.

The reactance controller may be connected in parallel to the transceiver.

The temperature sensor may be connected in parallel to the transceiver.

The reactance controller may be further configured to reduce a common mode frequency of the transceiver in response to the temperature of the transceiver being greater than or equal to the reference value.

According to an aspect of another exemplary embodiment, there is provided a magnetic resonance imaging (MRI) apparatus including a radio frequency (RF) receiving coil configured to receive an RF signal from an object, in an RF reception mode, a temperature sensor configured to sense a temperature of the MRI apparatus in an RF transmission mode in which the RF receiving coil ceases the reception of the RF signal from the object, and a reactance controller configured to control a reactance of the RF receiving coil in response to the temperature of the MRI apparatus being greater than or equal to a reference value, in the RF transmission mode.

According to an aspect of another exemplary embodiment, there is provided a method of controlling a local coil apparatus, the method including: sensing a temperature of the local coil apparatus, and controlling a reactance of an radio frequency receiving coil in response to the temperature of the local coil apparatus being greater than or equal to a reference value.

### BRIEF DESCRIPTION OF THE DRAWINGS

The above and/or other aspects will be more apparent by describing exemplary embodiments with reference to the accompanying drawings.

FIG. 1 is a control block diagram of an MRI apparatus according to an exemplary embodiment.

FIG. 2 is a diagram of an outer appearance of the MRI apparatus of FIG. 1.

FIG. 3 is a diagram of space where an object is placed, according to an exemplary embodiment.

FIG. 4 is a diagram of a structure of a magnet assembly and a structure of a gradient coil of the MRI apparatus of FIG. 1.

FIG. 5 is a diagram illustrating pulse sequences related to operations of individual gradient coils constituting the gradient coil of the MRI apparatus of FIG. 1.

FIGS. 6, 7, and 8 are perspective views of outer appearances of local coil apparatuses according to exemplary embodiments.

FIG. 9 is a control block diagram of a local coil apparatus according to an exemplary embodiment.

FIGS. 10, 11, and 12 are circuit diagrams of a local coil connected to a decoupling circuit, according to exemplary embodiments.

FIG. 13 is a graph showing current-to-frequency curves of signals that are transmitted or received in an RF transmission mode and an RF reception mode, according to an exemplary embodiment.

FIG. 14 is a circuit diagram of a decoupling circuit connected to a temperature sensor and a reactance controller, according to an exemplary embodiment.

FIG. 15 is a graph showing an RF reception frequency that is adjusted according to a result of control by the reactance controller of FIG. 14.

FIG. 16 is a flowchart illustrating a control method of a local coil apparatus, according to an exemplary embodiment.

FIG. 17 is a control block diagram of a local coil apparatus according to another exemplary embodiment.

FIG. 18 is a diagram illustrating a common mode trap.

FIG. 19 is a circuit diagram of a temperature sensor and a reactance controller, according to another exemplary embodiment.

FIG. 20 is a flowchart illustrating a control method of a local coil apparatus, according to another exemplary embodiment.

### DETAILED DESCRIPTION

Exemplary embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the exemplary embodiments. However, it is apparent that the exemplary embodiments can be practiced without those specifically defined matters. Also, well-known functions or constructions may not be described in detail because they would obscure the description with unnecessary detail.

It will be understood that, although the terms first, second, etc. may be used herein to describe various elements, these elements may not be limited by these terms. These terms are only used to distinguish one element from another. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present.

The terminology used herein is for the purpose of describing the exemplary embodiments only and is not intended to be limiting. As used herein, the singular forms “a,” “an,” and “the,” are intended to include the plural forms as well, unless the context clearly indicates otherwise.

In addition, the terms such as “unit,” “-er (-or),” and “module” described in the specification refer to an element for performing at least one function or operation, and may be implemented in hardware, software, or the combination of hardware and software.

Hereinafter, exemplary embodiments of a medical imaging apparatus and a control method thereof will be described in detail with reference to the accompanying drawings.

A diagnosis apparatus to which a medical imaging apparatus and a control method thereof according to exemplary embodiments can be applied or used may be one among an X-ray imaging apparatus, a Fluoroscopy X-ray apparatus, a Computerized Tomography (CT) scanner, a Magnetic Resonance Imaging (MRI) apparatus, Positron Emission Tomography (PET), and an ultrasonic imaging apparatus. In the following description about the exemplary embodiments, an MRI apparatus will be described as an example; however, the exemplary embodiments are not limited to the MRI apparatus.

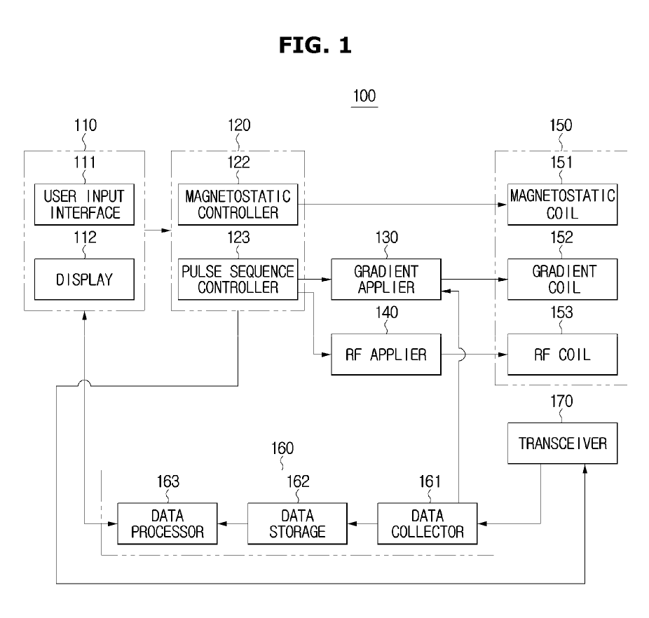

FIG. 1 is a control block diagram of an MRI apparatus according to an exemplary embodiment. Hereinafter, operations of an MRI apparatus will be described with reference to FIG. 1.

Referring to FIG. 1, an MRI apparatus 100 according to an exemplary embodiment may include a magnet assembly 150 configured to form a magnetic field and to generate a resonance phenomenon for atomic nuclei, a controller 120 configured to control operations of the magnet assembly 150, an image processor 160 configured to receive echo signals, that is, Magnetic Resonance (MR) signals generated from the atomic nuclei to create a MR image, and a transceiver 170 configured to transmit/receive data to/from an external device.

The magnet assembly 150 may include a magnetostatic coil 151 to form a static field in the inside space, a gradient coil 152 to generate a gradient in the static field to form a gradient magnetic field, and an RF coil 153 to apply RF pulses to excite atomic nuclei and to receive echo signals from the atomic nuclei. That is, if an object is positioned in the inside space of the magnetic assembly 150, a static field, a gradient magnetic field, and RF pulses may be applied to the object to excite atomic nuclei constituting the object, so that echo signals are generated from the atomic nuclei.

The controller 120 may include a magnetostatic controller 122 to control the intensity and direction of a static field formed by the magnetostatic coil 151, and a pulse sequence controller 123 to design a pulse sequence and to control the gradient coil 152 and the RF coil 153 according to the pulse sequence.

Each of the magnetostatic controller 122 and the pulse sequence controller 123 may include a memory to store programs and data for performing its functions, and a processor to perform the functions according to the programs and data stored in the memory.

According to an exemplary embodiment, the magnetostatic controller 122 and the pulse sequence controller 123 may be configured with separate memories and processors, or with a single memory and a single processor.

The MRI apparatus 100 may include a gradient applier 130 to apply a gradient signal to the gradient coil 152, and an RF applier 140 to apply an RF signal to the RF coil 153, so that the pulse sequence controller 123 controls the gradient applier 130 and the RF applier 140 to adjust a gradient magnetic field formed in the inside space of the magnetic assembly 150 and RF applied to atomic nuclei.

The RF coil 153 may be connected to the image processor 160, and the image processor 160 may include a data collector 161 to receive data about spin echo signals, that is, MR signals generated from atomic nuclei, and to process the data to create a MR image, a data storage 162 to store data received by the data collector 161, and a data processor 163 to process the stored data to create a MR image.

The data collector 161 may include a preamplifier to amplify a MR signal received by the RF coil 153, a phase detector to receive the MR signal from the preamplifier and to detect the phase of the MR signal, and an Analog-to-Digital (A/D) converter to convert an analog signal acquired by the phase detection into a digital signal. The data collector 161 may transmit the MR signal converted into the digital signal to the data storage 162.

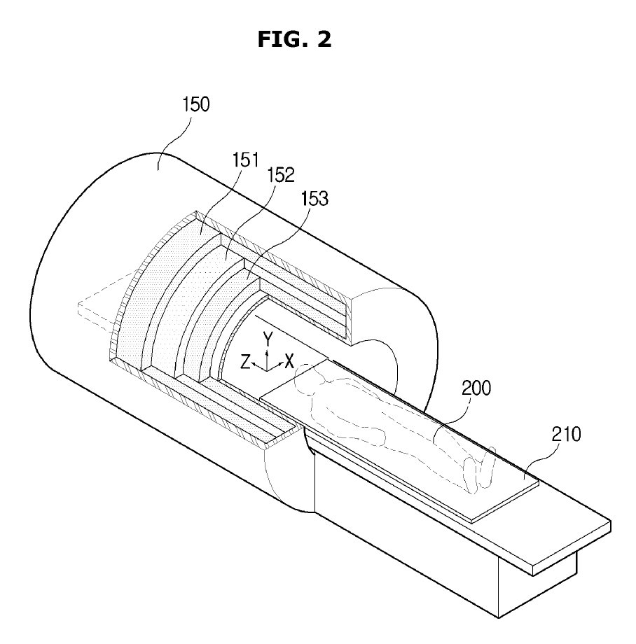

The data storage 162 may form data space configuring two-dimensional (2D) Fourier space, and if all scanned data is stored, the data processor 163 may perform inverse Fourier transform on the data in the 2D Fourier space to reconfigure an image about an object 200 (see FIG. 2). The reconfigured image may be displayed on a display 112.

The data storage 162 may be implemented as a memory to store programs and data used by the data processor 163 to reconfigure an image, and the data processor 163 may include a processor to generate control signals according to the programs and data stored in the memory.

According to another exemplary embodiment, the image processor 160 may be omitted. For example, the image processor 160 may be integrated into the controller 120, and in this case, the controller 120 may create a MR image.

Also, the MRI apparatus 100 may include a user interface 110 to receive control commands for overall operations of the MRI apparatus 100 from a user. The user interface 110 may receive a command for a scan sequence from the user to create a pulse sequence according to the command.

The user interface 110 may include a user input interface 111 to enable the user to manipulate the MRI apparatus 100, and the display 112 to display a controlled state and images created by the image processor 160 so that the user can diagnose an object's health status.

The transceiver 170 may be connected to an external device to transmit and receive data.

The transceiver 170 may be a terminal that can connect to the cable of an external device, or a cable that can connect to the terminal of an external device.

The transceiver 170 may be connected to the MRI apparatus 100 through a wired/wireless communication network, instead of a cable.

The wired/wireless communication network may include a wired communication network, a wireless communication network, a short-range communication network, and a combination of the wired communication network, the wireless communication network, and the short-range communication network.

The wired communication network may be directly connected to the MRI apparatus 100 through a wire connected to a terminal (for example, a Universal Serial Bus (USB) terminal or an Auxiliary (AUX) terminal) of the MRI apparatus 100. Also, the wired communication network may include wired Ethernet, a Wide Area Network (WAN), a Value Added Network (VAN), and the like.

The wireless communication network may support IEEE802.11x standards of the Institute of Electrical and Electronics Engineers (IEEE). Also, the wireless communication network may support Code Division Multiple Access (CDMA), Frequency Division Multiple Access (FDMA), Time Division Multiple Access (TDMA), Orthogonal Frequency Division Multiple Access (OFDMA), Single Carrier Frequency Division Multiple Access (SC-FDMA), and the like. The CDMA may be implemented with radio technology, such as Universal Terrestrial Radio Access (UTRA) or CDMA2000. The TDMA may be implemented with radio technology, such as Global System for Mobile communications (GSM), General Packet Radio Service (GPRS), or Enhanced Data rates for GSM Evolution (EDGE). The OFDMA may be implemented with radio technology, such as the IEEE 802.11 (Wi-Fi), the IEEE 802.16 (WiMAX), the IEEE 802.20, Evolved-UTRA (E-UTRA), and the like. The IEEE802.16m is an evolved version of the IEEE 802.16e, and provides backward compatibility with the system, based on the IEEE 802.16e. The UTRA may be a part of the Universal Mobile Telecommunications System (UMTS). The 3rd Generation Partnership Project Long Term Evolution (3GPP LTE), which is a part of the E-UMTS using the E-UTRA, may adopt OFDMA in a downlink and SC-FDMA in a uplink. The LTE-Advanced (LTE-A) is an evolved version of the 3GPP LTE.

The short-range communication network may support various short-range communication methods, such as Bluetooth, Bluetooth Low Energy (BLE), Infrared Data Association (IrDA), Wireless-Fidelity (Wi-Fi), Wi-Fi Direct, Ultra Wideband (UWB), Near Field Communication (NFC), Zigbee, and the like.

For example, the transceiver 170 may transmit a control signal generated by the controller 160 to an external device.

As another example, the transceiver 170 may receive data collected by an external device, and transfer the received data to the data collector 161 of the image processor 160.

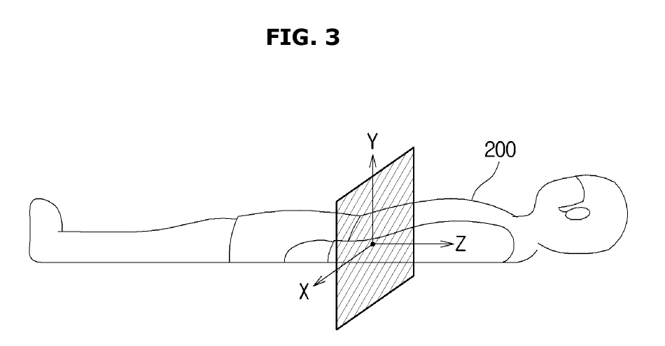

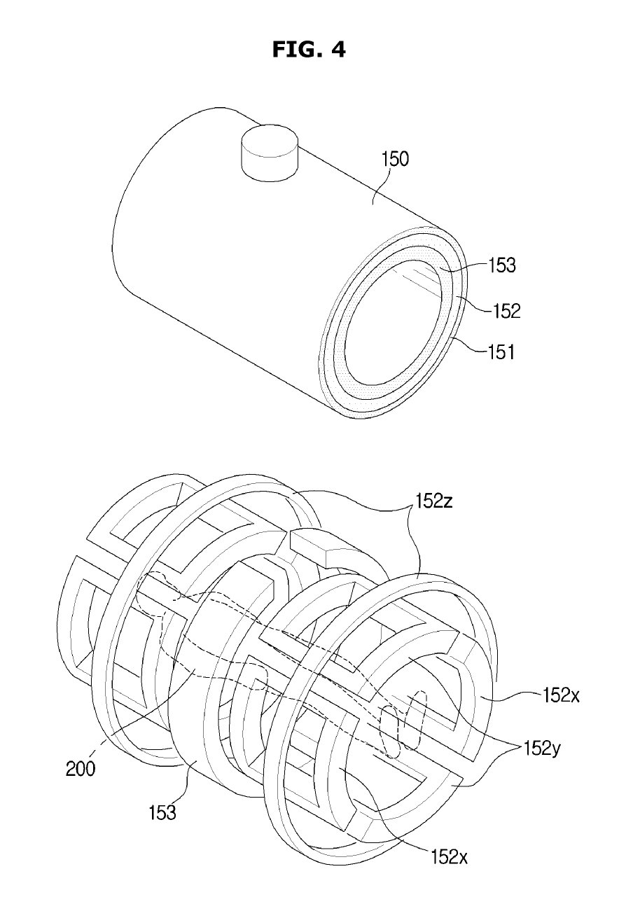

FIG. 2 is a diagram of an outer appearance of the MRI apparatus of FIG. 1, FIG. 3 is a diagram of a space where an object is placed, according to an exemplary embodiment, and FIG. 4 is a diagram of a structure of a magnet assembly and a structure of a gradient coil of the MRI apparatus of FIG. 1.

Hereinafter, operations of the MRI apparatus 100 according to an exemplary embodiment will be described in detail with reference to FIGS. 1 to 4.

Referring to FIG. 2, the magnet assembly 150 may be in the shape of a cylinder having empty inside space, and is also called a gantry or a bore. The inside space is also called cavity, and a conveyer 210 may transfer an object 200 lying thereon into the cavity to acquire a MR signal.

The magnet assembly 150 may include the magnetostatic coil 151, the gradient coil 152, and the RF coil 153.

The magnetostatic coil 151 may be in the shape of coils wound around the cavity. If current is applied to the magnetostatic coil 151, a static field may be formed in the inside space (that is, the cavity) of the magnet assembly 150.

The direction of the static field may be parallel to the coaxial line of the magnet assembly 150.

If a static field is formed in the cavity, the nuclei of atoms, e.g., hydrogen atoms constituting the object 200 may be aligned in the direction of the static field, and undergo a precession with respect to the direction of the static field. The precession velocity of the atomic nuclei can be represented as a precession frequency called a Larmor frequency. The Larmor frequency can be expressed by Equation (1) below.

ω=γB0, (1)

where ω is the Larmor frequency, γ is a proportional constant, and B0 is the intensity of an external magnetic field. The proportional constant depends on the kind of the atomic nuclei, the intensity of the external magnetic field is in units of Tesla (T) or Gauss (G), and the precession frequency is in units of Hz.

For example, because hydrogen protons have a precession frequency of 42.58 MHz in an external magnetic field of 1 T, and the major portion of atoms constituting the human body is hydrogen, the MRI acquires a MR signal using the precession of hydrogen protons.

The gradient coil 152 may generate a gradient in the static field formed in the cavity to form a gradient magnetic field.

As shown in FIG. 3, an axis parallel to the up-down direction of the object 200 from the head of the object 200 to the feet of the object 200, that is, an axis parallel to the direction of the static field may be defined as a z axis, an axis parallel to the left-right direction of the object 200 may be defined as an x axis, and an axis parallel to the up-down direction of the space may be defined as a y axis.

To acquire 3D spatial information for a MR signal, gradient magnetic fields for all the x, y, and z axes may be used. Accordingly, the gradient coil 152 may include three pairs of gradient coils.

As shown in FIG. 4, z-axis gradient coils 152z may be configured with a pair of ring type coils, and y-axis gradient coils 152y may be respectively positioned above and below the object 200. Also, x-axis gradient coils 152x may be respectively located to the left and right of the object 200.

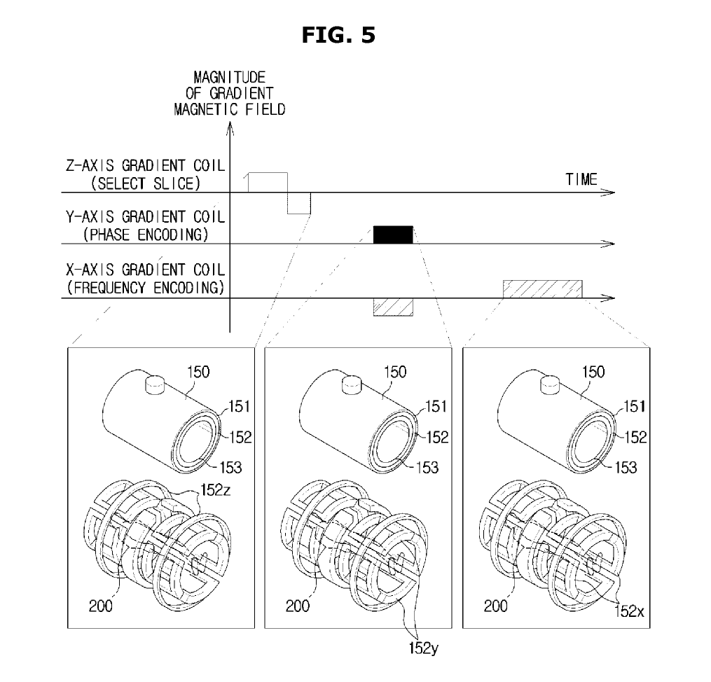

FIG. 5 is a diagram illustrating pulse sequences related to operations of individual gradient coils constituting the gradient coil of the MRI apparatus of FIG. 1.

If direct current having opposite polarities flows in opposite directions through the two z-axis gradient coils 152z, a change in magnetic field may occur in the z-axis direction to form a gradient magnetic field.

By causing current to flow through the z-axis gradient coils 152z for a predetermined time period to form a gradient magnetic field, a resonance frequency may change according to the magnitude of the gradient magnetic field. Then, if a high-frequency signal corresponding to a location is applied through the RF coil 153, only protons of a section corresponding to the location may cause resonance. Accordingly, the z-axis gradient coils 152z may be used to select a slice. Also, as the gradient of the gradient magnetic field formed in the z-axis direction is greater, the thinner slice can be selected.

If a slice is selected through the gradient magnetic field formed by the z-axis gradient coils 152z, spins configuring the slice may have the same frequency and the same phase so that the spins cannot be distinguished from each other.

At this time, if a gradient magnetic field is formed in the y-axis direction by the y-axis gradient coils 152y, the gradient magnetic field may cause phase shift such that the rows of the slice have different phases.

That is, if the y-axis gradient magnetic field is formed, the phases of the spins of rows to which a high gradient magnetic field is applied may change to a high frequency, and the phases of the spins of rows to which a low gradient magnetic field is applied may change to a low frequency. If the y-axis gradient magnetic field disappears, the individual rows of the selected slice may be subject to phase shift to have different phases so that the rows can be distinguished from each other. As such, a gradient magnetic field formed by the y-axis gradient coils 152y may be used for phase encoding.

If a slice is selected through a gradient magnetic field formed by the z-axis gradient coils 152z, the phases of the rows configuring the selected slice can be distinguished through a gradient magnetic field formed by the y-axis gradient coils 152y. However, because spins configuring each row have the same frequency and the same phase, the spins cannot be distinguished from each other.

At this time, if a gradient magnetic field is formed in the x-axis direction by the x-axis gradient coils 152x, the x-axis gradient magnetic field may cause the spins configuring each row to have different frequencies so that the spins can be distinguished from each other. As such, the gradient magnetic field formed by the x-axis gradient coils 152x may be used for frequency encoding.

As described above, the gradient magnetic fields formed by the x-, y-, and z-axis gradient coils 152x, 152y, and 152z may spatially encode the spatial positions of the individual spins through slice selection, phase encoding, and frequency encoding.

The gradient coil 152 may be connected to the gradient applier 130, and the gradient applier 130 may apply current pulses to the gradient coil 152 according to a control signal received from the pulse sequence controller 123 to thus form a gradient magnetic field. The gradient applier 130 can be called a gradient power source, and may include three driving circuits in correspondence to the three pairs of gradient coils 152x, 152y, and 152z constituting the gradient coil 152. Details about the configuration and operations of the gradient applier 130 will be described later.

As described above, atomic nuclei aligned by an external magnetic field may undergo a precession at the Larmor frequency, and a sum of magnetization vectors of several atomic nuclei can be represented as net magnetization M.

The z-axis component of the net magnetization M cannot be measured so that only Mxy can be detected. Accordingly, to acquire a MR signal, atomic nuclei are excited so that net magnetization M exists on the XY plane. To excite the atomic nuclei, RF pulses tuned to the Larmor frequency of the atomic nuclei may be applied to a static field.

The RF coil 153 may include an RF transmitting coil to transmit RF pulses, and an RF receiving coil to receive electronic waves (that is, a MR signal) emitted from excited atomic nuclei.

Also, the RF transmitting coil may be a whole-volume coil to transmit RF pulses to the entire of an object, and the RF receiving coil may be divided into a whole-volume coil to receive a MR signal excited in the entire of the object, and a local coil or a surface coil to receive a MR signal excited in a part of the object. Accordingly, the whole-volume coil can function as both an RF transmitting coil and an RF receiving coil, whereas the local coil can function as only an RF receiving coil.

The whole-volume coil is also called a body coil. The whole-volume coil may be provided on the magnet assembly 150 and included in the RF coil 153. However, the local coil may be provided on an external device (hereinafter, referred to as a “local coil apparatus”) independently from the MRI apparatus 100, and connected to the MRI apparatus 100 through a transceiver such as a cable, to thus transmit data about a MR signal generated from atomic nuclei to the image processor 160.

The RF coil 153 may be connected to the RF applier 140, and the RF applier 140 may apply a high-frequency signal to the RF coil 153 according to a control signal received from the pulse sequence controller 123 to cause the RF coil 153 to transmit RF pulses to the inside of the magnet assembly 150.

The RF applier 140 may include a modulation circuit to modulate a high-frequency signal into a pulsed signal, and an RF power amplifier to amplify the pulsed signal.

One among methods used for acquiring a MR signal from atomic nuclei is a spin echo pulse sequence. When the RF coil 153 applies RF pulses, the RF coil 153 may apply a first RF pulse, and then transmit an RF pulse once more with an appropriate time interval Δt. Thereafter, when a time period of Δt elapses, strong traverse magnetization may occur in atomic nuclei to acquire a MR signal. This process is called a spin echo pulse sequence, and a time taken until a MR signal is generated after the first RF pulse is applied is called Time Echo (TE).

How protons flip may be represented as an angle formed with respect to an axis on which the protons were positioned before they flip, and can be represented as a 90° RF pulse, a 180° RF pulse, etc., according to a degree of flip.

In the following description, the RF receiving coil is assumed to be a local coil provided on a local coil apparatus and configured to receive a MR signal excited in a part of an object.

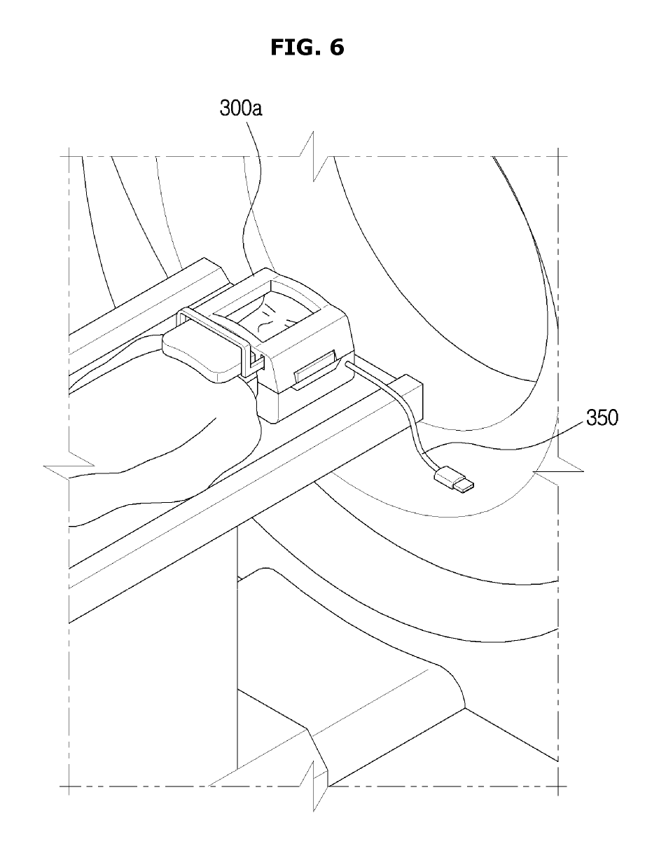

FIGS. 6, 7, and 8 are perspective views of outer appearances of local coil apparatuses according to exemplary embodiments.

A local coil apparatus 300 (that is, 300a, 300b, or 300c) may include a local coil to receive a MR signal excited in a part of an object, and a transceiver 350 connected to the magnet assembly 150 and configured to transmit a MR signal to the image processor 160. In the following description, the transceiver 350 of the local coil apparatus 300 is assumed to be a cable.

As shown in FIG. 6, the local coil apparatus 300a may be implemented as a head coil apparatus to scan the head of an object, and to receive a MR signal excited in the head of the object.

A plurality of local coils may be provided in the head coil apparatus 300a, and the plurality of local coils may receive an echo signal, that is, a MR signal generated from the head of an object Data about the MR signal may be transmitted to the image processor 160 through the cable 350 so that a MR image about the head of the object can be created.

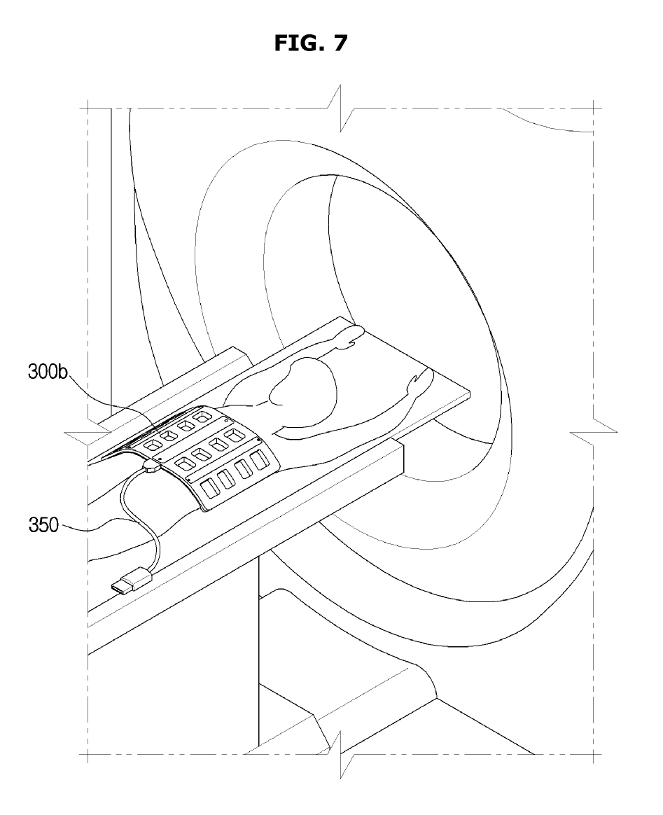

Also, as shown in FIG. 7, the local coil apparatus 300b may be implemented as a thoracoabdominal coil apparatus to scan the chest or abdomen of an object, and to receive a MR signal excited in the chest or abdomen of the object.

Likewise, a plurality of local coils may be provided in the thoracoabdominal coil apparatus 300b, and the plurality of local coils may receive an echo signal, that is, a MR signal generated from the chest or abdomen of an object, so that a MR image about the chest or abdomen of the object can be created.

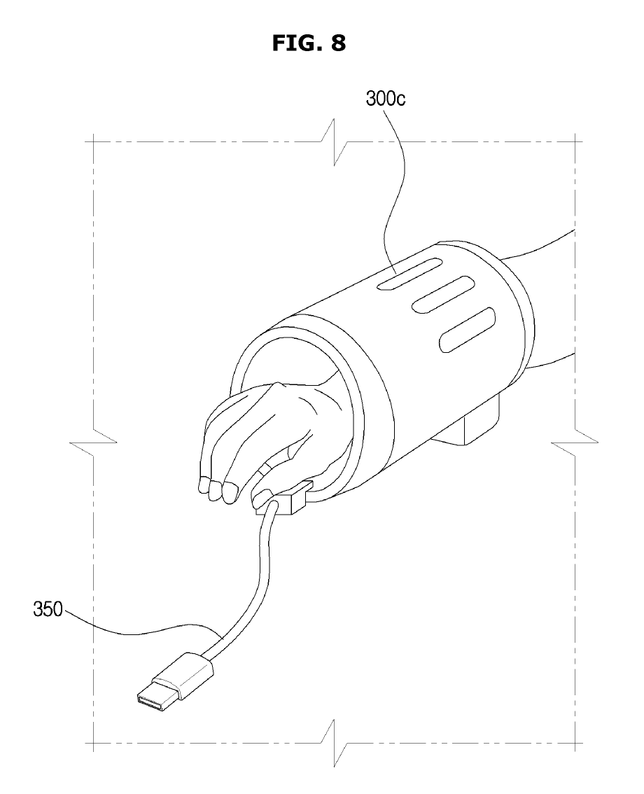

Also, as shown in FIG. 8, the local coil apparatus 300c may be implemented as a local coil apparatus to scan a local part of an object, and to receive a MR signal excited in the local part of the object. Herein, the local part may be any part of the object, such as an arm, a leg, etc.

Likewise, a plurality of local coils may be provided in the local coil apparatus 300c, and the plurality of local coils may receive an echo signal, that is, a MR signal generated from a local part of an object, so that a MR image about the local part of the object can be created.

If the cable 350 is connected to the MRI apparatus 100, the local coils provided in the local coil apparatus 300 may be electrically connected to the RF coil 153 provided in the MRI apparatus 100.

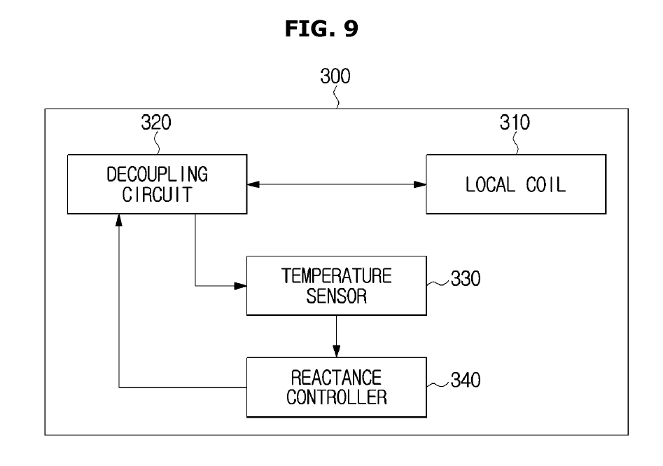

The local coil apparatus 300 according to an exemplary embodiment will be described in more detail with reference to FIGS. 9, 10, 11, 12, 13, 14, and 15 below.

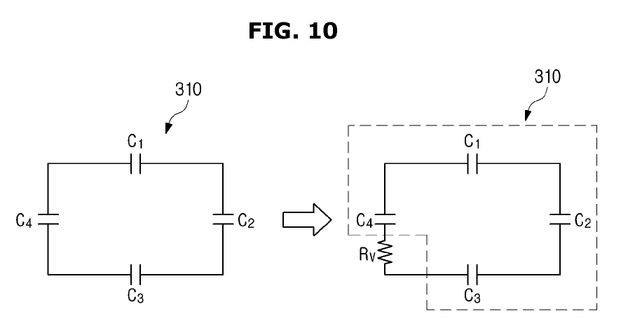

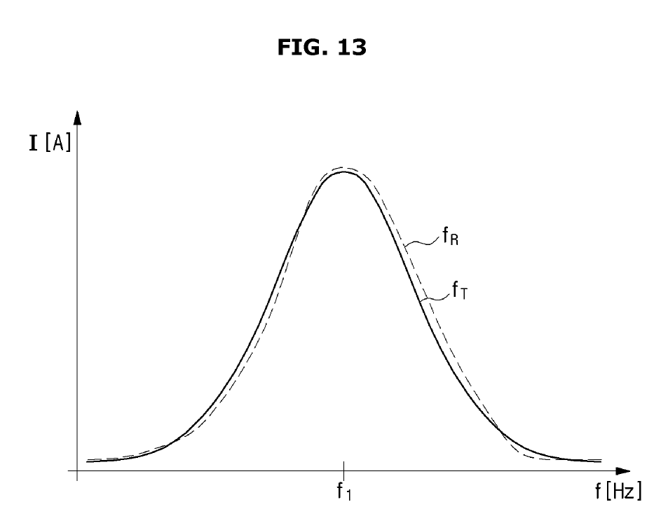

FIG. 9 is a control block diagram of a local coil apparatus according to an exemplary embodiment, FIGS. 10, 11, and 12 are circuit diagrams of a local coil connected to a decoupling circuit, according to exemplary embodiments, and FIG. 13 is a graph showing current-to-frequency curves of signals that are transmitted or received in an RF transmission mode and an RF reception mode, according to an exemplary embodiment.

Referring to FIG. 9, the local coil apparatus 300 may include a local coil 310 to receive a MR signal excited in an object, a decoupling circuit 320 to control the local coil 310 to receive an RF signal, a temperature sensor 330 to sense the temperature of the decoupling circuit 320, and a reactance controller 340 to control the reactance of the decoupling circuit 320, based on the result of the sensing by the temperature sensor 330.

The decoupling circuit 320 is also called a de-tuning circuit, and may block induced current flowing through the local coil 310 in the RF transmission mode in which an RF signal is transmitted from the RF coil 153 of the MRI apparatus 100, and cause current to flow through the local coil 310 to receive an RF signal in the RF reception mode in which the RF signal is received through the local coil 310.

In detail, the decoupling circuit 320 may increase the impedance of the local coil 310 in the RF transmission mode to thereby prevent current from flowing through the local coil 310, and may decrease the impedance of the local coil 310 in the RF reception mode to thereby cause current to flow through the local coil 310.

For example, the decoupling circuit 320 may be implemented as a variable resistor whose impedance increases in the RF transmission mode and decreases in the RF reception mode. The variable resistor may be a diode, for example, a PIN diode.

The decoupling circuit 320 will be described in more detail with reference to FIGS. 10, 11, and 12, later.

The temperature sensor 330 may be a temperature sensor to sense the temperature of the decoupling circuit 320, and the temperature sensor may output the sensed temperature as a voltage corresponding to the sensed temperature.

For example, if the decoupling circuit 320 includes a diode, the temperature sensor 330 may sense the temperature of the diode.

The reactance controller 340 may control the reactance of the decoupling circuit 320, based on the temperature of the decoupling circuit 340 sensed by the temperature sensor 330.

In detail, when the temperature sensor 330 outputs a voltage proportional to the temperature of the decoupling circuit 320 as a result value, if the result value of the temperature sensor 330 is greater than or equal to an output reference value, that is, if the temperature of the decoupling circuit 320 is greater than or equal to a temperature reference value (for example, 41° C.), the reactance controller 340 may control the reactance of the decoupling circuit 320 to reduce the decoupling frequency of the local coil 310.

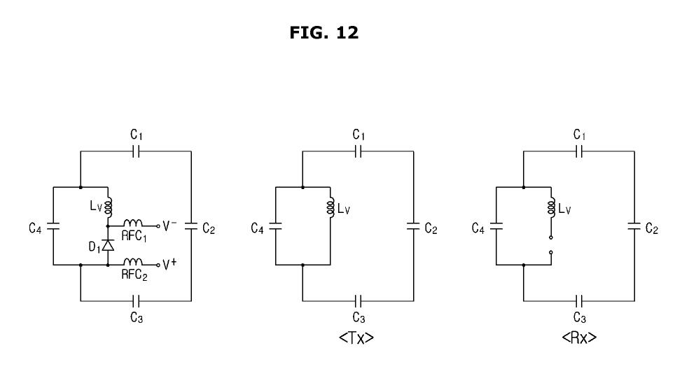

Herein, the decoupling frequency means a frequency formed in the local coil 310 by the reactance of the decoupling circuit 320 and other components (C₁, C₂, and C₃ of FIG. 12) of the local coil 310.

When the temperature sensor 330 outputs a voltage inverse-proportional to the temperature of the decoupling circuit 320 as a result value, if the result value of the temperature sensor 330 is less than or equal to the output reference value, that is, if the temperature of the decoupling circuit 320 is greater than or equal to the temperature reference value (for example, 41° C.), the reactance controller 340 may control the reactance of the decoupling circuit 320 to reduce the decoupling frequency of the local coil 310.

The RF transmitting coil of the MRI apparatus 100 may apply a RF pulse tuned to the Larmor frequency to an object to excite atomic nuclei in the RF transmission mode. However, because the Larmor frequency is a high frequency (for example, 42.68 MHz or 123.48 MHz), if the RF transmitting coil tunes a transmission frequency to such a high frequency, a high decoupling frequency may be formed in the RF receiving coil although the decoupling circuit 320 exists, resulting in generation of high heat.

Accordingly, the reactance controller 340 according to an exemplary embodiment may increase effective capacitance of the decoupling circuit 320 if the result value of the temperature sensor 330 is greater than or equal to the output reference value, thereby reducing the decoupling frequency (w=1\sqrt{LC}).

For example, the reactance controller 340 may be implemented as a varactor diode whose capacitance increases if the result value of the temperature sensor 330 is greater than or equal to the output reference value.

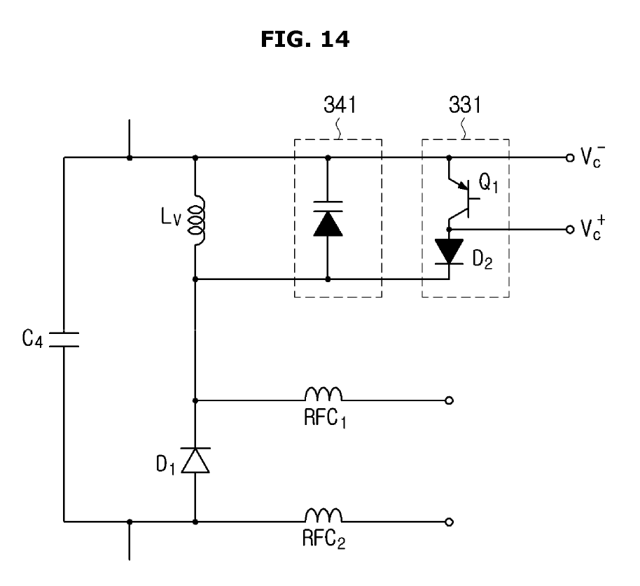

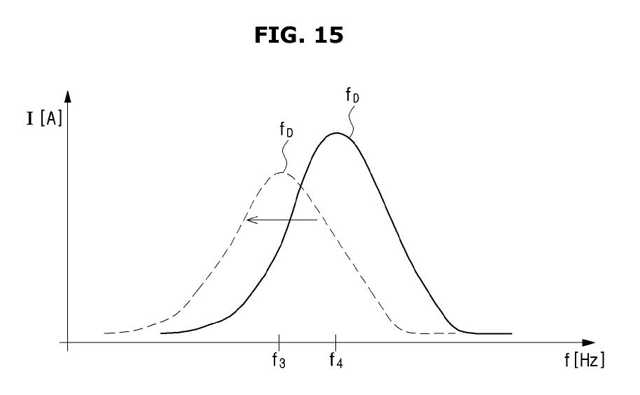

Details about the reactance controller 340 will be described in more detail with reference to FIGS. 14 and 15 below.

The local coil 310, the decoupling circuit 320, the temperature sensor 330, and the reactance controller 340 may be implemented as a single module or a single circuit, or as separate modules connected to each other.

Hereinafter, for convenience of description, the local coil 310, the decoupling circuit 320, the temperature sensor 330, and the reactance controller 340, implemented as a single module will be described.

Referring to FIG. 10, the local coil 310 according to an exemplary embodiment may include a plurality of capacitors C₁ to C₄ connected in series to each other, and the plurality of capacitors C₁ to C₄ may be connected through a wire functioning as an inductor (that is, a coil).

The local coil 310 may receive a MR signal excited in an object in the RF reception mode, and due to the structural characteristics of the circuit, induced current may be generated even in the RF transmission mode. The induced current may generate latent heat in the local coil 310, and because the local coil 310 is adjacent to the object, the object may have a burn due to such latent heat.

Accordingly, in the RF transmission mode, induced current may be blocked. The local coil 310 according to an exemplary embodiment may further include a variable resistor Rᵥ connected in series to control current flowing through the local coil 310.

The impedance of the variable resistor Rᵥ may increase in the RF transmission mode and decrease in the RF reception mode so that current flowing through the local coil 310 can decrease in the RF transmission mode and increase in the RF reception mode. The impedance of the variable resistor Rᵥ in the RF transmission mode may have a great enough value to block current flowing through the local coil 310, and the impedance of the variable resistor Rᵥ in the RF reception mode may have a small value such that the local coil 310 is hardly influenced by the variable resistor Rᵥ.

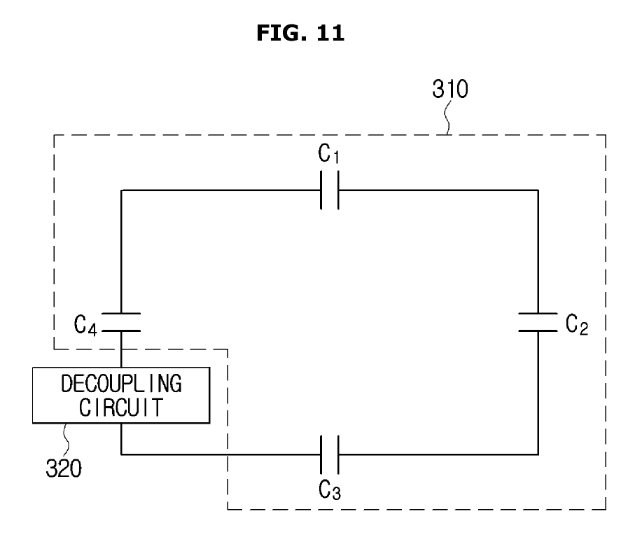

Referring to FIG. 11, the local coil 310 according to an exemplary embodiment may be connected to the decoupling circuit 320 functioning as a variable resistor.

The decoupling circuit 320 may perform control operation of blocking current flowing through the local coil 310 in the RF transmission mode in which an RF signal is transmitted from the RF coil 153 of the MRI apparatus 100, and of causing current to flow through the local coil 310 in the RF reception mode in which an RF signal is received through the local coil 310.

The decoupling circuit 320 may be connected in series to the local coil 310, as shown in FIG. 11. Hereinafter, a circuit diagram and an operation method of the decoupling circuit 320 will be described in detail with reference to FIG. 12.

Referring to FIG. 12, the decoupling circuit 320 according to an exemplary embodiment may include a diode D₁ and an inductor Lᵥ connected in series to each other, and a capacitor C₄ connected in parallel to the diode D₁ and the inductor Lᵥ connected in series to each other. In this case, the decoupling circuit 320 may be connected in series to a plurality of capacitors C₁ to C₃ constituting the local coil 310.

The diode D₁ may be a PIN diode.

The anode of the diode D₁ may be connected to a positive (+) terminal of a power supply to supply a voltage to the circuit. Accordingly, when a voltage +V is supplied from the anode of the diode D₁ and a voltage −V is supplied from the cathode of the diode D₁, a forward voltage may be supplied to the diode D₁. When a voltage −V is supplied from the anode of the diode D₁ and a voltage +V is supplied from the cathode of the diode D₁, a backward voltage may be supplied to the diode D₁.

A voltage to be applied to the diode D₁ may depend on a control signal. The control signal may be a signal received from the controller 120 of the MRI apparatus 100 through the cable 350, or a signal received from a controller installed in the local coil apparatus 300. The controller installed in the local coil apparatus 300 may include a memory to store data and programs for determining whether to supply a forward voltage or a backward voltage according to the RF transmission mode or the RF reception mode, and a processor to perform functions according to the programs and data stored in the memory.

If a forward voltage is applied from the power supply to the diode D₁, current may flow from the bottom to the top of the diode D₁, as seen in FIG. 12.

In the RF transmission mode Tx, a forward voltage may be applied so that current flows through the diode D₁. For example, a voltage V may be applied to the diode D₁ to cause current of 100 mA to flow through the diode D₁. Because current flows through the diode D₁, the diode D₁ can be represented as an equivalent circuit having low resistance as if it is shorted. The low resistance may be, for example, 0.50.

In the RF transmission mode Tx, because the diode D₁ is shorted, a parallel resonance circuit may be formed by the inductor Lᵥ and the capacitor C₄. Accordingly, both terminals of the capacitor C₄ may become a high-impedance state, and a decoupling state in which no magnetic coupling with the other components C₁, C₂, and C₃ is formed.

Accordingly, in the RF transmission mode Tx, if an RF pulse tuned to the Larmor frequency from the RF transmitting coil of the MRI apparatus 100 is applied to an object, induced current may hardly flow through the local coil apparatus 300 due to the decoupling state of the local coil 310, so that latent heat caused by such induced current can also be barely generated.

In the RF reception mode Rx, a backward voltage may be applied to the diode D₁, or no voltage may be applied to the diode D₁. Accordingly, current may hardly flow through the diode D₁, and the major portion of current may flow through the capacitor C₄ connected in parallel to the diode D₁. Because little current flows through the diode D₁, the diode D₁ can be represented as an equivalent circuit having high resistance as if it is opened. The high resistance may be, for example, 50 kΩ.

In the RF reception mode Rx, a signal may be extracted from both terminals of the capacitor C₄ of the decoupling circuit 320, or a signal may be extracted from both terminals of any one among the capacitors C₁, C₂, and C₃ of the local coil 310, and the extracted signal may be transmitted to the image processor 160 of the MRI apparatus 100 through the cable 350.

In the RF reception mode Rx, signals may be collected at the same frequency (that is, the Larmor frequency) as that of an RF pulse applied to an object in the RF transmission mode Tx. That is, as shown in FIG. 13, signals may be collected in the same frequency band f_{R} as a RF transmission frequency band f_{T} in a high-frequency (f₁) band.

However, if an RF pulse is applied in the high-frequency (f₁) band in the RF transmission mode Tx, a high decoupling frequency may be formed in the local coil 310. Accordingly, induced current may increase due to the decoupling frequency although the decoupling circuit 320 exists, and latent heat may be generated in the circuit. Because the local coil 310 is adjacent to the object, an increase in temperature of the local coil 310 may greatly influence the object, and accordingly, the increase in temperature of the local coil 310 is considered as a factor.

Accordingly, the local coil apparatus 300 according to an exemplary embodiment may further include the temperature sensor 330 and the reactance controller 340 to adjust the decoupling frequency of the circuit according to the result of sensing by the temperature sensor 330, thereby reducing the temperature of the local coil 310.

FIG. 14 is a circuit diagram of a decoupling circuit connected to a temperature sensor and a reactance controller, according to an exemplary embodiment, and FIG. 15 is a graph showing an RF reception frequency that is adjusted according to a result of control by the reactance controller of FIG. 14.

Referring to FIG. 14, the temperature sensor 330 may be implemented as a temperature sensor 331 including a diode D₂ and a transistor Q₁ functioning as a switch. In the RF transmission mode Tx, the temperature sensor 330 may sense the temperature of the diode D₁. The diode D₂ may output the sensed temperature as a voltage value.

In the RF reception mode Rx, no voltage may be applied to the transistor Q₁, and accordingly, the temperature sensor 330 may not operate.

In the RF transmission mode Rx, a voltage V_{c}⁺ or V_{c}⁻ may be applied to the transistor Q₁, and a temperature reference value or an output reference value may be decided based on the voltage V_{c}⁺ or V_{c}⁻ applied to the transistor Q₁. Also, the diode D₂ may output a voltage value corresponding to the temperature of the diode D₁ to the reactance controller 340.

The voltage V_{c}⁺ or V_{c}⁻ applied to the transistor Q₁ may vary according to a control signal of the MRI apparatus 100 or a control signal of the controller installed in the local coil apparatus 301.

The reactance controller 340 may be implemented as, for example, a varactor diode 341. The varactor diode 341 may be connected in parallel to the temperature sensor 331, and also may be connected in parallel to the inductor Lᵥ of the decoupling circuit 320.

The varactor diode 341 may change the reactance of the decoupling circuit 320 according to an input voltage value. In detail, the varactor diode 341 may change capacitance according to an input voltage value to thus change the reactance of the decoupling circuit 320, and if the reactance of the decoupling circuit 320 changes, the total reactance of the local coil apparatus 300 may change.

If the reactance of the local coil apparatus 300 changes, the resonance frequency of the circuit may change accordingly so that the decoupling frequency can change.

That is, referring to FIG. 15, if the temperature sensor 330 senses temperature greater than or equal to a temperature reference value (for example, 41° C.) when a decoupling frequency f_{D} is formed in a frequency band f₄ in the RF transmission mode, the varactor diode 341 may change the reactance of the decoupling circuit 320 to reduce the decoupling frequency f_{D} to a frequency band f₃, and accordingly, current flowing through the local coil 310 may decrease so that the temperature of the local coil 310 can decrease.

Referring to FIGS. 12 and 14, a first blocking inductor RFC₁ for blocking residual current flowing from the decoupling circuit 320 to the negative (−) terminal of the power source may be disposed between the diode D₁ and the negative (−) terminal of the power source. Likewise, a second blocking inductor RFC₂ for blocking residual current flowing from the decoupling circuit 320 to the positive (+) terminal of the power source may be further disposed between the diode D₁ and the positive (+) terminal of the power source.

Also, a coupling capacitor may be further disposed between the diode D₁ and the inductor Lᵥ connected in series to each other, and included in the decoupling circuit 320.

According to an exemplary embodiment, the temperature sensor 330 configured with the transistor Q₁ and the diode D₂, and the reactance controller 340 implemented with the varactor diode 341, have been described. However, a circuit configuration of the temperature sensor 330 and the reactance controller 340 is not limited thereto.

Also, in an exemplary embodiment, the reactance controller 340 senses the temperature of only the diode D₁ of the decoupling circuit 320; however, the reactance controller 340 can sense the temperature of the decoupling circuit 320 or the other components of the local coil 310.

Also, in an exemplary embodiment, the local coil apparatus 300 including a single local coil 310 has been described; however, the local coil apparatus 300 may include a plurality of local coils 310.

Also, in an exemplary embodiment, the local coil 310 includes three capacitors C₁, C₂, and C₃, and the decoupling circuit 320 includes the inductor Lᵥ, the diode D₁, and the capacitor C₄. However, the capacitor C₄ of the decoupling circuit 320 may configure a part of the local coil 310.

In this case, the decoupling circuit 320 may include the diode D₁ and the inductor Lᵥ connected in series to each other, and the decoupling circuit 320 may be connected in parallel to any one among the plurality of capacitors C₁ to C₄.

The local coil 310 and the decoupling circuit 320 may further include other components in addition to the above-described components, and exemplary embodiments are not limited to the circuit diagram shown in FIG. 14.

Also, in an exemplary embodiment, the RF receiving coil provided in the local coil apparatus 300 is assumed; however, the RF receiving coil may be provided as a whole-volume coil of the MRI apparatus 100. To implement the RF receiving coil as a whole-volume coil of the MRI apparatus 100, the MRI apparatus 100 may also include the same components as the local coil apparatus 300. In this case, the term “local coil 310” mentioned in an exemplary embodiment can be replaced with the term “whole-volume coil,” and the term “local coil apparatus 300” mentioned in an exemplary embodiment can be replaced with the term “MRI apparatus 100.”

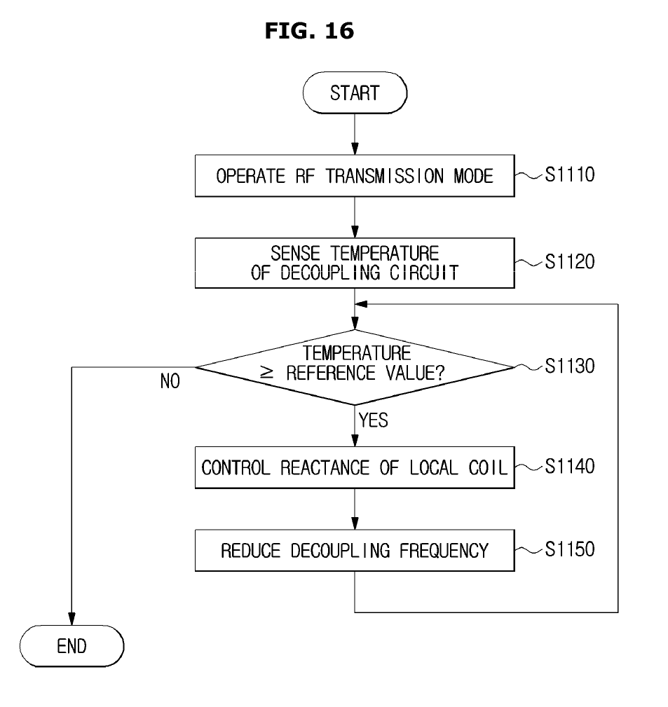

Hereinafter, a control method of the local coil apparatus 300 according to an exemplary embodiment will be described with reference to FIG. 16.

FIG. 16 is a flowchart illustrating a control method of a local coil apparatus, according to an exemplary embodiment.

The individual components of the local coil apparatus 300 and the MRI apparatus 100, which will be described below, may be the same as the corresponding ones of the local coil apparatus 300 and the MRI apparatus 100 described above with reference to FIGS. 1 to 15, and accordingly, like components will be indicated by like reference numerals.

In operation S1110, a control method of the local coil apparatus 300 according to an exemplary embodiment includes operating an RF transmission mode.

Operation of operating the RF transmission mode may include operation of applying a forward voltage to the diode D₁ of the decoupling circuit 320 so that no induced current is generated in the local coil 310 that is an RF receiving coil.

Also, operation of operating the RF transmission mode may include operation of driving the temperature sensor 330. If the temperature sensor 330 is implemented as the temperature sensor 331 including the transistor Q₁, operation of operating the RF transmission mode may include operation of applying a predetermined voltage to the transistor Q₁.

Operation of operating the RF transmission mode may be performed by the controller 120 of the MRI apparatus 100 or the controller installed in the local coil apparatus 300.

In operation S1120, the control method of the local coil apparatus 300 according to an exemplary embodiment includes the temperature of the decoupling circuit 320.

For example, if the decoupling circuit 320 includes the diode D₁, operation of sensing the temperature of the decoupling circuit 320 may include operation of sensing the temperature of the diode D₁.

Operation of sensing the temperature of the decoupling circuit 320 may be performed by the temperature sensor 330 included in the local coil apparatus 300. In this case, the temperature sensor 330 may output a voltage value corresponding to the temperature of the decoupling circuit 320.

In operation S1130, the control method of the local coil apparatus 300 according to an exemplary embodiment includes determining whether the sensed temperature of the decoupling circuit 320 is greater than or equal to a temperature reference value.

For example, if the temperature sensor 330 outputs a voltage proportional to the temperature of the decoupling circuit 320 as a result value, operation of determining whether the temperature is greater than or equal to the temperature reference value may include operation of determining whether the result value of the temperature sensor 330 is greater than or equal to an output reference value.

If the temperature sensor 330 outputs a voltage inverse-proportional to the temperature of the decoupling circuit 320 as a result value, operation of determining whether the temperature is greater than or equal to the temperature reference value may include operation of determining whether the result value of the temperature sensor 330 is less than or equal to the output reference value.

Operation of determining whether the temperature is greater than or equal to the temperature reference value may be performed by the reactance controller 340 of the local coil apparatus 300.

If the temperature of the decoupling circuit 320 is greater than or equal to the temperature reference value, in operation S1140, the control method of the local coil apparatus 300 according to an exemplary embodiment includes controlling the reactance of the local coil 310 to thereby reduce a decoupling frequency in operation S1150. Otherwise, the control method ends.

For example, when the temperature sensor 330 outputs a voltage proportional to the temperature of the decoupling circuit 320 as a result value, operation of controlling the reactance of the local coil 310 may include operation of controlling the reactance of the decoupling circuit 320 to reduce the decoupling frequency of the local coil 310, if the result value of the temperature sensor 330 is greater than or equal to the output reference value, that is, if the temperature of the decoupling circuit 320 is greater than or equal to the temperature reference value (for example, 41° C.).

When the temperature sensor 330 outputs a voltage inverse-proportional to the temperature of the decoupling circuit 320 as a result value, operation of controlling the reactance of the local coil 310 may include operation of controlling the reactance of the decoupling circuit 320 to reduce the decoupling frequency of the local coil 310, if the result value of the temperature sensor 330 is less than or equal to an output reference value, that is, if the temperature of the decoupling circuit 320 is greater than or equal to a temperature reference value (for example, 41° C.).

Operation of controlling the reactance of the local coil 310 to reduce the decoupling frequency of the local coil 310 may be performed by the reactance controller 340 of the local coil apparatus 300.

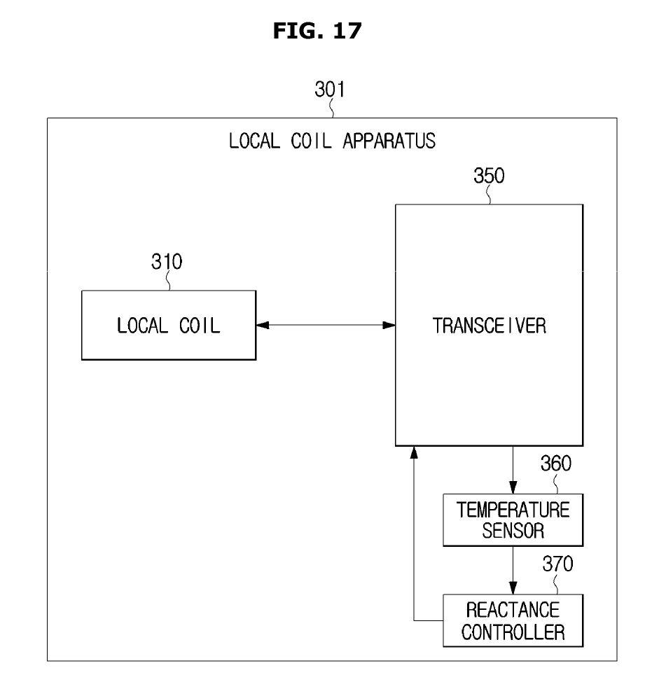

Hereinafter, a local coil apparatus according to another exemplary embodiment will be described. FIG. 17 is a control block diagram of a local coil apparatus according to another exemplary embodiment.

Referring to FIG. 17, a local coil apparatus 301 according to another exemplary embodiment may include a local coil 310, a transceiver 350, a temperature sensor 360, and a reactance controller 370.

In FIG. 17, the local coil apparatus 301 includes a single local coil 310; however, the local coil apparatus 301 may include a plurality of local coils 310. That is, the number of local coils 310 is not limited.

The local coil 310 has been described above with reference to FIGS. 1 to 15, and accordingly, a further description thereof will be omitted.

The transceiver 350 may receive a control signal from the MRI apparatus 100, or transmit signals collected by the local coil 310 in the RF reception mode to the MRI apparatus 100.

The transceiver 350 may be implemented as the cable 350 described above with reference to FIGS. 6, 7, and 8, and the cable 350 of the local coil apparatus 301 may be connected to a terminal of the MRI apparatus 100 or the transceiver 170 implemented as a cable, to enable the local coil apparatus 301 to transmit/receive data to/from the MRI apparatus 100.

The transceiver 350 may be connected to the MRI apparatus 100 through a wired/wireless communication network, instead of a cable.

The wired/wireless communication network may include a wired communication network, a wireless communication network, a short-range communication network, and a combination of the wired communication network, the wireless communication network, and the short-range communication network, as described above.

Hereinafter, for convenience of description, the transceiver 350 of the local coil apparatus 301 implemented as a cable and the transceiver 170 of the MRI apparatus 100 implemented as a terminal will be described as examples.

For example, the cable 350 of the local coil apparatus 301 may receive a control signal for controlling a voltage that is supplied to the local coil 310 according to the RF transmission mode or the RF reception mode, from the terminal 170 of the MRI apparatus 100.

As another example, the cable 350 of the local coil apparatus 301 may transmit data collected by the local coil 310 in the RF reception mode to the image processor 160 of the MRI apparatus 100 through the terminal 170 of the MRI apparatus 100.

If the cable 350 is connected to the MRI apparatus 100, a virtual circuit may be formed between the local coil apparatus 301 and the MRI apparatus 100. Theoretically, the virtual circuit may not make any noise; however, actual noise may be made by the impedance of the cable 350 or the terminal 170. Such noise is called a common mode trap.

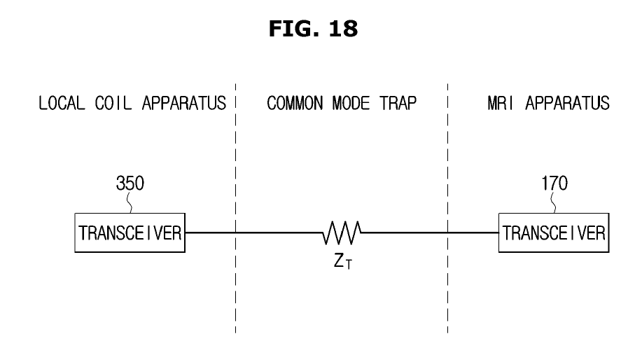

FIG. 18 is a diagram illustrating a common mode trap.

Referring to FIG. 18, the common mode trap may be represented as a virtual circuit including an impedance device Z_{T}. By the common mode trap, the impedance of the cable 350 may increase, and the temperature of the cable 350 may rise.

Accordingly, referring again to FIG. 17, the local coil apparatus 301 according to another exemplary embodiment may include the temperature sensor 360 to sense the temperature of the cable 350 due to the impedance of the common mode trap, and the reactance controller 370 to control reactance due to the common mode trap, according to the sensed temperature.

The temperature sensor 360 may sense the temperature of the cable 350.

The temperature sensor 360 may be a temperature sensor for sensing the temperature of the cable 350, and the temperature sensor may output the sensed temperature as a voltage corresponding to the sensed temperature.

The reactance controller 370 may control the reactance of the common mode trap, based on the result of sensing by the temperature sensor 360.

In detail, when the temperature sensor 360 outputs a voltage proportional to the temperature of the cable 350 as a result value, if the result value of the temperature sensor 360 is greater than or equal to a reference value, that is, if the temperature of the cable 350 is greater than or equal to a reference value (for example, 41° C.), the reactance controller 370 may control the reactance of the cable 350 to reduce a common mode frequency.

The common mode frequency means a frequency formed at the cable 350 by the reactance of the common mode trap.

When the temperature sensor 360 outputs a voltage inverse-proportional to the temperature of the cable 350 as a result value, if the result value of the temperature sensor 360 is less than or equal to an output reference value, that is, if the temperature of the cable 350 is greater than or equal to a temperature reference value (for example, 41° C.), the reactance controller 370 may control the reactance of the cable 350 to reduce the common mode frequency.

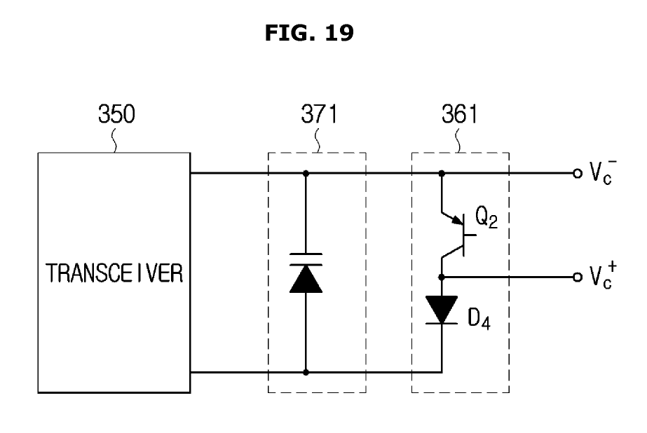

FIG. 19 is a circuit diagram of a temperature sensor and a reactance controller, according to another exemplary embodiment.

Referring to FIG. 19, the temperature sensor 360 may be a temperature sensor 361 including a transistor Q₂ and a diode D₄, and may sense the temperature of the cable 350 in the RF transmission mode. Herein, the diode D₄ may output the sensed temperature as a voltage value.

To drive the transistor Q₂, a voltage V_{c}⁺ or V_{c}⁻ may be applied to the transistor Q₂, according to a control signal of the MRI apparatus 100 or a control signal of the controller installed in the local coil apparatus 301, and a reference value may be decided based on the voltage V_{c}⁺ or V_{c}⁻ applied to the transistor 0₂. Also, the diode D₄ may output a voltage value corresponding to the temperature of the cable 350 to the reactance controller 370.

The reactance controller 370 may be implemented as, for example, a varactor diode 371. The varactor diode 371 may be connected in parallel to the temperature sensor 361, for example, to both terminals of the cable 350, as shown in FIG. 19. However, the varactor diode 371 may be connected in series to the cable 350.

The varactor diode 371 may change the reactance of the cable 350 according to an input voltage value. In detail, the varactor diode 371 may change the capacitance of the cable 350 to thereby change the reactance of the cable 350. Accordingly, the common mode frequency of the cable 350 can change.

That is, if the temperature sensor 361 senses temperature greater than or equal to a reference value (for example, 41° C.), the varactor diode 371 may change the reactance of the cable 350 to reduce the common mode frequency of the cable 350, and accordingly, the temperature of the cable 350 can be reduced.

Another exemplary embodiment described above relates to the temperature sensor 360 configured with the transistor Q₂ and the diode D₄, and the reactance controller 370 implemented as the varactor diode 371, however, a circuit configuration of the temperature sensor 360 and the reactance controller 370 is not limited to this.

Also, another exemplary embodiment described above relates to the local coil apparatus 301 including a single local coil 310; however, the local coil apparatus 301 may include a plurality of local coils 310.

Also, in another exemplary embodiment described above, the transceiver 350 is a cable; however, the transceiver 350 may be a wired/wireless communication apparatus connecting the local coil apparatus 301 to the MRI apparatus 100, instead of a cable.

Also, the local coil apparatus 301 may further include other components in addition to the above-described components, and the exemplary embodiments are not limited to the shown circuit diagram.

Also, in another exemplary embodiment described above, the RF receiving coil provided in the local coil apparatus 301 is assumed; however, the RF receiving coil may be provided as a whole-volume coil of the MRI apparatus 100. To implement the RF receiving coil as a whole-volume coil of the MRI apparatus 100, the MRI apparatus 100 may also include the same components as the local coil apparatus 301. In this case, the term “local coil 310” mentioned in another exemplary embodiment described above can be replaced with the term “whole-volume coil,” the term “local coil apparatus 301” mentioned in another exemplary embodiment described above can be replaced with the term “MRI apparatus 100,” and the term “transceiver 350” mentioned in another exemplary embodiment described above can be replaced with the term “transceiver 170.”

Also, another exemplary embodiment described above has been described in regard of the RF receiving coil of the local coil apparatus 301; however, another exemplary embodiment described above can also be applied to the RF receiving coil of the MRI apparatus 100. In this case, the term “local coil 310” mentioned in another exemplary embodiment described above can be replaced with the term “whole-volume coil,” the term “local coil apparatus 301” mentioned in another exemplary embodiment described above can be replaced with the term “MRI apparatus 100,” and the term “transceiver 350” mentioned in another exemplary embodiment described above can be replaced with the term “transceiver 170.” Accordingly, the decoupling frequency of the MRI apparatus 100 can also be controlled.

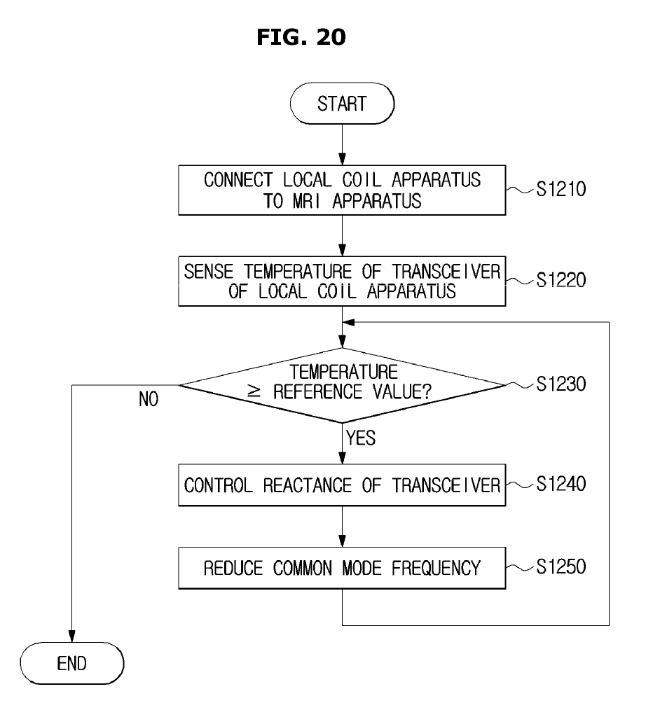

Hereinafter, a control method of the local coil apparatus 301 according to another exemplary embodiment will be described with reference to FIG. 20.

FIG. 20 is a flowchart illustrating a control method of a local coil apparatus, according to another exemplary embodiment.

The individual components of the local coil apparatus 301 and the MRI apparatus 100, which will be described below, may be the same as the corresponding ones of the local coil apparatus 301 and the MRI apparatus 100 described above with reference to FIGS. 17 to 19, and accordingly, like components will be indicated by like reference numerals.

In operation S1210, the control method of the local coil apparatus 301 according to another exemplary embodiment includes electrically connecting the local coil apparatus 301 to the MRI apparatus 100.

Operation of electrically connecting the local coil apparatus 301 to the MRI apparatus 100 may include operation of connecting the transceiver 350 of the local coil apparatus 301 to the transceiver 170 of the MRI apparatus 100.

Operation of electrically connecting the local coil apparatus 301 to the MRI apparatus 100 may be performed manually by a user, or automatically by a separate connection controller for controlling connection.

In operation S1220, the control method of the local coil apparatus 301 according to another exemplary embodiment includes sensing the temperature of the transceiver 350 of the local coil apparatus 301.

Operation of sensing the temperature of the transceiver 350 of the local coil apparatus 301 may be performed by the temperature sensor 360 included in the local coil apparatus 301. In this case, the temperature sensor 360 may output a voltage value corresponding to the temperature of the transceiver 350 of the local coil apparatus 301.

In operation S1230, the control method of the local coil apparatus 301 according to another exemplary embodiment includes determining whether the sensed temperature of the transceiver 350 of the local coil apparatus 300 is greater than or equal to a temperature reference value.

For example, if the temperature sensor 360 outputs a voltage proportional to the temperature of the transceiver 350 of the local coil apparatus 301 as a result value, operation of determining whether the temperature is greater than or equal to the temperature reference value may include operation of determining whether the result value of the temperature sensor 360 is greater than or equal to an output reference value.

If the temperature sensor 360 outputs a voltage inverse-proportional to the temperature of the transceiver 350 of the local coil apparatus 301 as a result value, operation of determining whether the temperature is greater than or equal to the temperature reference value may include operation of determining whether the result value of the temperature sensor 360 is less than or equal to the output reference value.

Operation of determining whether the temperature is greater than or equal to the temperature reference value may be performed by the reactance controller 370 of the local coil apparatus 301.

If the temperature of the transceiver 350 of the local coil apparatus 301 is greater than or equal to the temperature reference value, in operation S1240, the control method of the local coil apparatus 301 according to another exemplary embodiment includes controlling the reactance of the transceiver 350 to reduce a common mode frequency in operation S1250.

For example, if the temperature sensor 360 outputs a voltage proportional to the temperature of the transceiver 350 of the local coil apparatus 301 as a result value, operation of controlling the reactance of the transceiver 350 may control the reactance of the cable 350 to reduce a common mode frequency of the transceiver 350, if the result value of the temperature sensor 360 is greater than or equal to an output reference value, that is, if the temperature of the transceiver 350 of the local coil apparatus 301 is greater than or equal to a temperature reference value (for example, 41° C.).

If the temperature sensor 360 outputs a voltage inverse-proportional to the temperature of the transceiver 350 of the local coil apparatus 301 as a result value, operation of controlling the reactance of the transceiver 350 may control the reactance of the cable 350 to reduce the common mode frequency of the transceiver 350, if the result value of the temperature sensor 360 is less than or equal to the output reference value, that is, if the temperature of the transceiver 350 of the local coil apparatus 301 is greater than or equal to the temperature reference value (for example, 41° C.).

Operation of controlling the reactance of the transceiver 350 to reduce the common mode frequency may be performed by the reactance controller 370 of the local coil apparatus 301.

According to the local coil apparatus, the MRI apparatus, and the control method of the local coil apparatus, as described above, by controlling the reactance of the circuit according to temperature, it is possible to reduce heat generated in the circuit due to frequency tuning or connection between the local coil apparatus and the MRI apparatus.

In addition, the exemplary embodiments may also be implemented through computer-readable code and/or instructions on a medium, e.g., a computer-readable medium, to control at least one processing element to implement any above-described embodiments. The medium may correspond to any medium or media that may serve as a storage and/or perform transmission of the computer-readable code.

The computer-readable code may be recorded and/or transferred on a medium in a variety of ways, and examples of the medium include recording media, such as magnetic storage media (e.g., ROM, floppy disks, hard disks, etc.) and optical recording media (e.g., compact disc read only memories (CD-ROMs) or digital versatile discs (DVDs)), and transmission media such as Internet transmission media. Thus, the medium may have a structure suitable for storing or carrying a signal or information, such as a device carrying a bitstream according to one or more exemplary embodiments. The medium may also be on a distributed network, so that the computer-readable code is stored and/or transferred on the medium and executed in a distributed fashion. Furthermore, the processing element may include a processor or a computer processor, and the processing element may be distributed and/or included in a single device.

The foregoing exemplary embodiments are examples and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. A local coil apparatus comprising:
a radio frequency (RF) receiving coil configured to receive an RF signal from an object;
a temperature sensor configured to sense a temperature of the local coil apparatus; and
a reactance controller configured to control a reactance of the RF receiving coil in response to the temperature of the local coil apparatus being greater than or equal to a reference value.

2. The local coil apparatus according to claim 1, further comprising a decoupling circuit configured to:
increase an impedance of the RF receiving coil in an RF transmission mode in which the RF receiving coil ceases the reception of the RF signal from the object; and
decrease the impedance of the RF receiving coil in an RF reception mode in which the RF receiving coil receives the RF signal from the object.

3. The local coil apparatus according to claim 2, wherein the temperature sensor is further configured to sense a temperature of the decoupling circuit, and
the reactance controller is further configured to control a reactance of the decoupling circuit in response to the temperature of the decoupling circuit being greater than or equal to the reference value.

4. The local coil apparatus according to claim 3, wherein the decoupling circuit comprises a diode, and
wherein the temperature sensor is further configured to sense a temperature of the diode.

5. The local coil apparatus according to claim 4, wherein the diode is a PIN diode.

6. The local coil apparatus according to claim 4, wherein the diode is configured to:
receive a voltage in a forward direction in the RF transmission mode; and
receive a voltage in a backward direction in the RF reception mode.

7. The local coil apparatus according to claim 2, wherein the decoupling circuit comprises a capacitor, an inductor, and a diode,
the inductor is connected in series to the diode, and
the inductor and the diode are connected in parallel to the capacitor.

8. The local coil apparatus according to claim 7, wherein the reactance controller is connected in parallel to the inductor.

9. The local coil apparatus according to claim 1, wherein the reactance controller comprises a varactor diode.

10. The local coil apparatus according to claim 1, wherein the reactance controller is further configured to reduce an RF reception frequency of the local coil apparatus in response to the temperature of the local coil apparatus being greater than or equal to the reference value.

11. The local coil apparatus according to claim 1, further comprising a transceiver connected to a Magnetic Resonance Imaging (MRI) apparatus to transmit an RF signal in an RF transmission mode,
wherein the temperature sensor senses temperature of the transceiver.

12. The local coil apparatus according to claim 11, wherein the transceiver comprises a cable.

13. The local coil apparatus according to claim 11, wherein the transceiver connected to the MRI apparatus has a common mode trap.

14. The local coil apparatus according to claim 13, wherein the common mode trap comprises an impedance.

15. The local coil apparatus according to claim 11, wherein the reactance controller is connected in parallel to the transceiver.

16. The local coil apparatus according to claim 11, wherein the temperature sensor is connected in parallel to the transceiver.

17. The local coil apparatus according to claim 11, wherein the reactance controller is further configured to reduce a common mode frequency of the transceiver in response to the temperature of the transceiver being greater than or equal to the reference value.

18. A magnetic resonance imaging (MRI) apparatus comprising:
a radio frequency (RF) receiving coil configured to receive an RF signal from an object, in an RF reception mode;
a temperature sensor configured to sense a temperature of the MRI apparatus in an RF transmission mode in which the RF receiving coil ceases the reception of the RF signal from the object; and
a reactance controller configured to control a reactance of the RF receiving coil in response to the temperature of the MRI apparatus being greater than or equal to a reference value, in the RF transmission mode.

19. A method of controlling a local coil apparatus, the method comprising:
sensing a temperature of the local coil apparatus; and
controlling a reactance of an radio frequency receiving coil in response to the temperature of the local coil apparatus being greater than or equal to a reference value.
